(19) United States
(12) Patent Application Publication
(10) Pub. No.: US 2024/0258370 A1
(43) Pub. Date: Aug. 1, 2024

(54) SEMICONDUCTOR COMPONENT

(71) Applicant: Industrial Technology Research Institute, Hsinchu (TW)

(72) Inventors: Hsueh-Hsing Liu, Taipei City (TW); Chia-Lung Tsai, Kaohsiung City (TW)

(73) Assignee: Industrial Technology Research Institute, Hsinchu (TW)

(21) Appl. No.: 18/542,737

(22) Filed: Dec. 17, 2023

Related U.S. Application Data
(60) Provisional application No. 63/482,302, filed on Jan. 31, 2023.

(30) Foreign Application Priority Data
Nov. 9, 2023 (TW) 112143297

(51) Int. Cl. H01L 29/06; H01L 29/778

(52) U.S. Cl. CPC H01L 29/0638; H01L 29/7786

(57) ABSTRACT

A semiconductor component including a semiconductor layer, a barrier layer, a leakage current suppression layer, an ohmic contact layer and an electrode layer is provided. The semiconductor layer has a protrusion and a top surface, adjacent to the protrusion. The protrusion includes a top surface and a side surface. The barrier layer is disposed on the top surface of the protrusion. The leakage current suppression layer is disposed on the top surface of the semiconductor layer. The ohmic contact layer is disposed on the leakage current suppression layer, and contacts the side surface of the protrusion and a side surface of the barrier layer. The ohmic contact layer does not contact the top surface of the semiconductor layer. The electrode layer is disposed on the ohmic contact layer.

### CROSS-REFERENCE TO RELATED APPLICATION

This application claims the priority benefit of U.S. provisional application Ser. No. 63/482,302, filed on Jan. 31, 2023, and Taiwan application Ser. No. 11/214,3297, filed on Nov. 9, 2023. The entirety of each of the above-mentioned patent applications is hereby incorporated by reference herein and made a part of this specification.

### BACKGROUND

### Technical Field

The invention relates to a semiconductor component.

### Description of Related Art

For application environments requiring high frequency of operation and high output power, semiconductor components need to have characteristics such as high breakdown voltage and high saturation carrier velocity. Gallium nitride has the wide band-gap characteristic. In addition, the polarization difference occurring at the interface of the heterostructure formed with gallium nitride and n-type aluminum gallium nitride induces two-dimensional electron gas, which is the mechanism of the high electron mobility transistor (HEMT). Therefore, components based on gallium nitride materials are adequate for applications in high frequency, high power, radiation resistant and high temperature environments. However, when a high frequency component is in operation, a small amount of current would leak downward from the ohmic contact layer under the source electrode and the drain electrode to the buffer layer. Therefore, how to solve the aforementioned problems is an issue of concern in the industry.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The present invention provides a semiconductor component that effectively prevents current from leaking downward to the buffer layer.

According to an embodiment of the present invention, a semiconductor component including a semiconductor layer, a barrier layer, two leakage current suppression layers, two ohmic contact layers and two electrode layers is provided. The semiconductor layer has a protrusion and two top surfaces of the semiconductor layer on a side of the semiconductor layer. The two top surfaces of the semiconductor layer are adjacent to the protrusion, the protrusion comprising a top surface and two side surfaces. One of the two side surfaces of the protrusion is adjacent between the top surface of the protrusion and one of two top surfaces of the semiconductor layer. The other one of the two side surfaces of the protrusion is adjacent between the top surface of the protrusion and the other one of two top surfaces of the semiconductor layer. The barrier layer is disposed on the top surface of the protrusion, wherein the barrier layer comprises two side surfaces. The two leakage current suppression layers are respectively disposed on the two top surfaces of the semiconductor layer. The two ohmic contact layers are respectively disposed on the two leakage current suppression layers, wherein the two ohmic contact layers are in contact with the two side surfaces of the protrusion and the two side surfaces of the barrier layer, and the two ohmic contact layers do not contact the two top surfaces of the semiconductor layer. The two electrode layers are respectively disposed on the two ohmic contact layers.

Based on the above description, in the semiconductor component provided by the embodiment of the present invention, the leakage current suppression layer is disposed between the ohmic contact layer and the semiconductor layer, wherein the ohmic contact layer is used to reduce contact resistance to increase high-frequency power gain. The leakage current suppression layer is used to prevent current from leaking downward to the buffer layer or the substrate of the semiconductor component when the semiconductor component is in operation, thereby reducing power consumption. Accordingly, the semiconductor component may have higher efficiency while the high-frequency power gain is improved. The semiconductor component is adequate for high frequency and high power related electronic products, such as B5G/6G communication products.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are schematic diagrams of a manufacturing method of a semiconductor component according to an embodiment of the present invention.

FIG. 2A to FIG. 2C are schematic diagrams of a manufacturing method of a semiconductor component according to an embodiment of the present invention.

FIG. 3 is a schematic diagram of a partial structure of a semiconductor component according to an embodiment of the present invention.

FIG. 4 is a schematic diagram of a partial structure of a semiconductor component according to an embodiment of the present invention.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

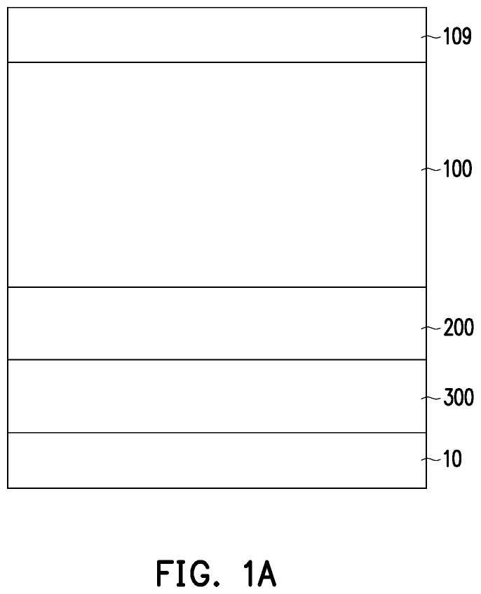

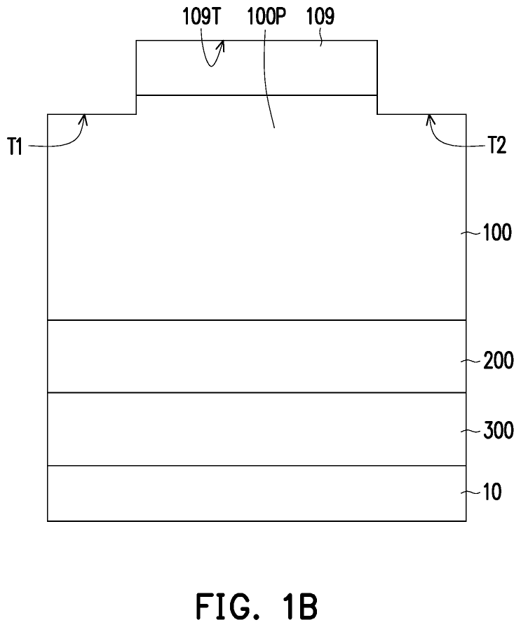

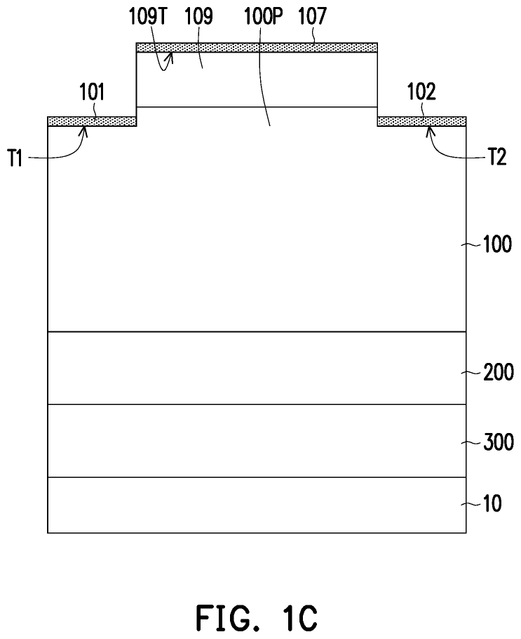

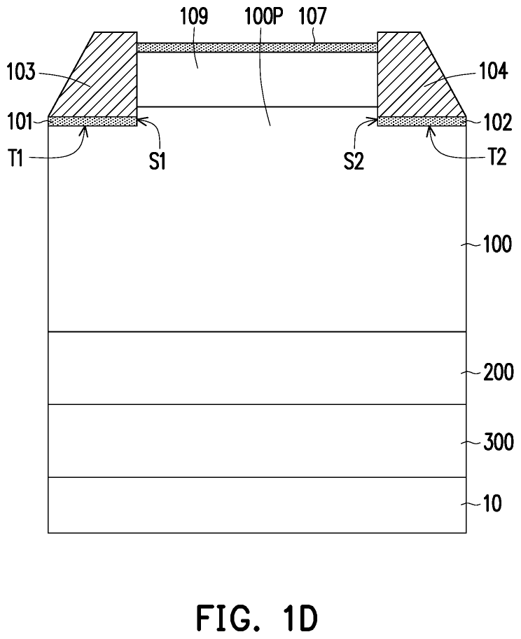

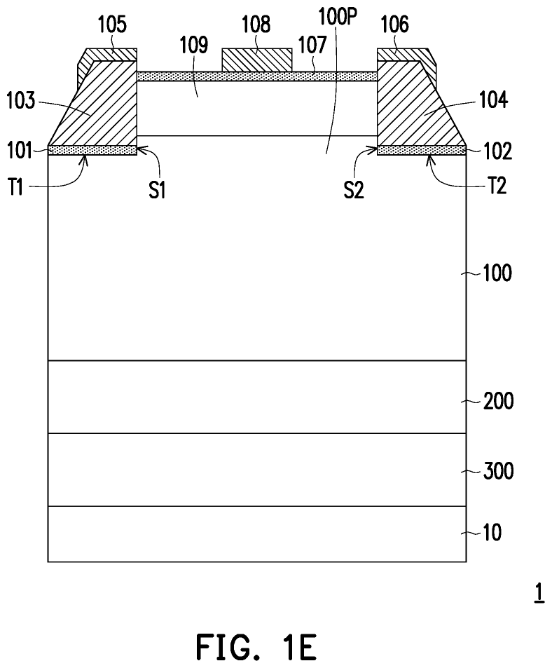

Referring to FIG. 1A to FIG. 1E, which are schematic diagrams of a manufacturing method of a semiconductor component according to an embodiment of the present invention.

First, referring to FIG. 1A, a substrate 10 is provided. The substrate includes, for example, a silicon layer, a silicon carbide layer, a SOI (Silicon on Insulator) layer, a QST (Qromis substrate technology) ceramic layer, or a combination thereof as a semiconductor layer.

Next, an aluminum nitride layer 300 is formed on the substrate 10. Generally speaking, when the aluminum nitride layer 300 is formed in a high-temperature process, the aluminum contained therein would diffuse into the film layer below it. Therefore, in some preferred embodiments, a wide band-gap diffusion buffer layer is formed on a side of the substrate 10 close to the aluminum nitride layer 300 to prevent aluminum in the aluminum nitride layer 300 from diffusing to the semiconductor layer of the substrate 10, which prevents current leakage from occurring in the substrate 10 of the manufactured semiconductor component in operation.

Next, the buffer layer 200 and the semiconductor layer 100 are sequentially formed on the aluminum nitride layer 300. The buffer layer 200 is an aluminum gallium nitride (AlGaN) layer, and the semiconductor layer 100 is a wide band-gap gallium nitride (GaN) layer. Since the difference in lattice constant between the substrate 10 and the GaN layer (semiconductor layer 100) thereon would cause stress and affect the quality of the epitaxial layer on the substrate 10, the buffer layer 200 is formed between the substrate 10 and the semiconductor layer 100 so as to balance the stress between the substrate 10 and the semiconductor layer 100 formed on the substrate 10.

Then, a barrier layer 109 is formed on the semiconductor layer 100. The barrier layer 109 is an aluminum gallium nitride layer, wherein the wide band-gap gallium nitride (GaN) of the semiconductor layer 100 and the barrier layer 109 form a heterostructure. (AlGaN/GaN heterostructure).

Refer to FIG. 1B. An etching process is performed on the barrier layer 109 and the semiconductor layer 100, so that a protrusion 100P and two top surfaces T1 and T2 are formed on the upper part of the semiconductor layer 100. The barrier layer 109 is located on the protrusion 100P.

Refer to FIG. 1C. Leakage current suppression layers 101, 102, and 107 are respectively formed on the two top surfaces T1 and T2 of the semiconductor layer 100 and the top surface 109T of the barrier layer 109. In some embodiments, the material of the leakage current suppression layers 101, 102, 107 includes one of SiO₂, SiN, Ga₂O₃, (AlₓGa₁₋ₓ)₂O₃, Al₂O₃, AlN, BN or alike wide band-gap materials, but the invention is not limited thereto.

Refer to FIG. 1D. Ohmic contact layers 103 and 104 are respectively formed on the leakage current suppression layers 101 and 102, wherein the ohmic contact layer 103 contacts the side surface S1 of the protrusion 100P, and the ohmic contact layer 104 contacts the side surface S2 of the protrusion 100P.

Refer to FIG. 1E. Electrode layers 105, 106, and 108 are respectively formed on the ohmic contact layers 103 and 104 and the leakage current suppression layer 107, and thereby the semiconductor component 1 is formed.

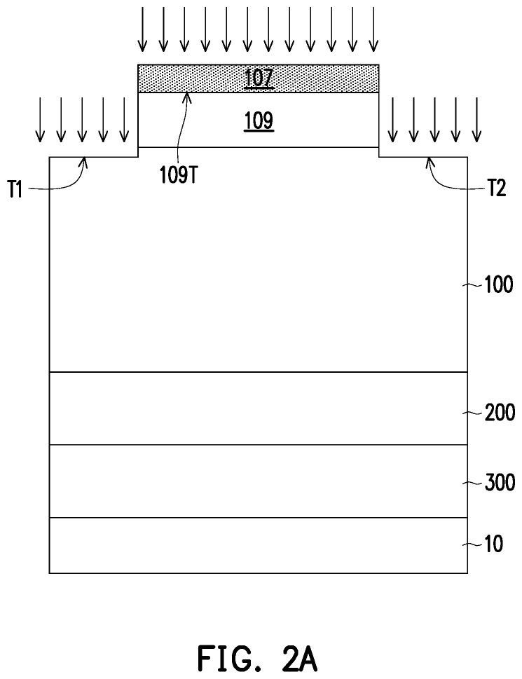

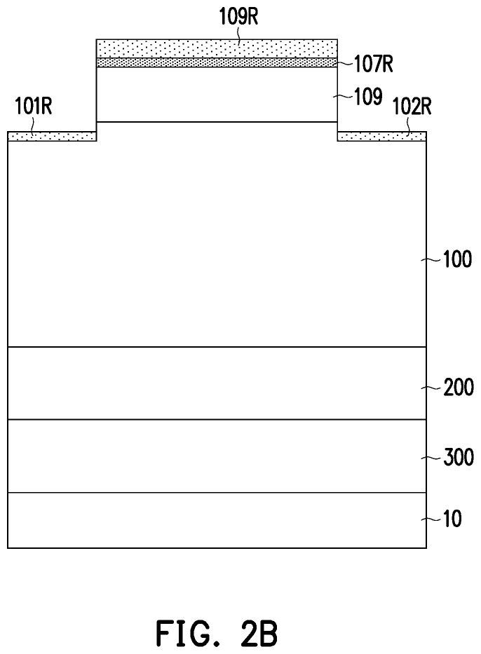

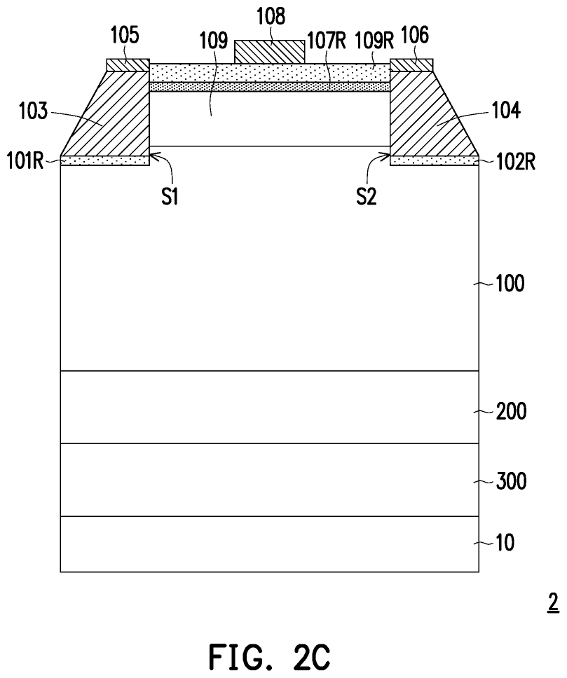

Next, please refer to FIG. 1A, FIG. 1B, FIG. 2A, FIG. 2B, and FIG. 2C in sequence, which illustrate schematic diagrams of a manufacturing method of a semiconductor component according to another embodiment of the present invention. The steps shown in FIG. 1A and FIG. 1B are described in the previous embodiment. Redundant description is omitted.

Refer to FIG. 2A and FIG. 2B simultaneously. First, the leakage current suppression layer 107 is formed on the top surface 109T of the barrier layer 109, and then the two top surfaces T1 and T2 of the semiconductor layer 100 and the leakage current suppression layer 107 are simultaneously implanted with ions to form the high resistance layers 101R, 102R, and 107R respectively.

Refer to FIG. 2C. Ohmic contact layers 103 and 104 are respectively formed on the high resistance layers 101R and 102R, wherein the ohmic contact layer 103 contacts the side surface S1 of the protrusion 100P, and the ohmic contact layer 104 contacts the side surface S2 of the protrusion 100P. Finally, electrode layers 105, 106, and 108 are formed on the ohmic contact layers 103, 104 and the high resistance layer 107R respectively, and thereby the semiconductor component 2 is formed.

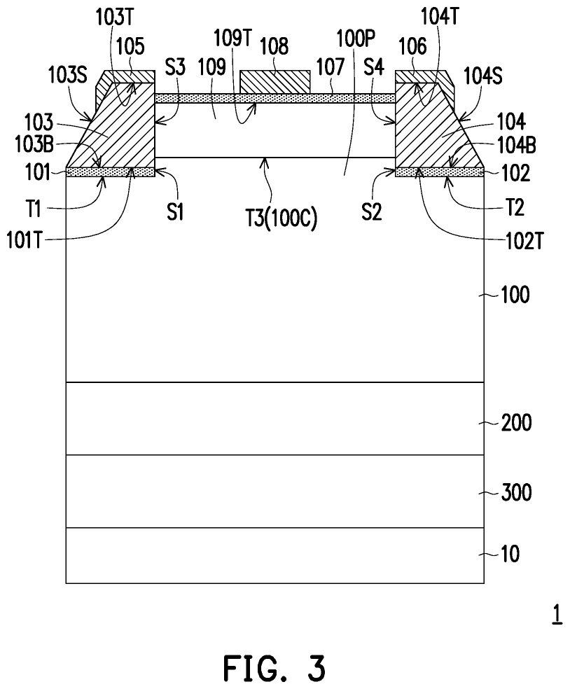

Refer to FIG. 3 for the understanding of the structure and function of the semiconductor component 1 in the aforementioned embodiment in detail. The semiconductor component 1 includes the substrate 10, the semiconductor layer 100, the buffer layer 200, the aluminum nitride layer 300, the two leakage current suppression layers 101 and 102, the two ohmic contact layers 103 and 104, the electrode layers 105, 106 and 108 and the barrier layer 109. The two electrode layers 105 and 106 are respectively disposed on the two ohmic contact layers 103 and 104.

A protrusion 100P and two top surfaces T1 and T2 of the semiconductor layer 100 adjacent to the protrusion 100P are present on one side of the semiconductor layer 100. The protrusion 100P includes a top surface T3 and the two side surfaces S1 and S2. The side surface S1 of the protrusion 100P is adjacent to the top surface T3 of the protrusion 100P and the top surface T1, and the side surface S2 of the protrusion 100P is adjacent to the top surface T3 of the protrusion 100P and the top surface T2. The barrier layer 109 is disposed on the top surface T3 of the protrusion 100P, wherein the barrier layer 109 includes two side surfaces S3 and S4.

The leakage current suppression layer 101 is disposed on the top surface T1, and the leakage current suppression layer 102 is disposed on the top surface T2. The ohmic contact layer 103 is disposed on the leakage current suppression layer 101 and contacts the side surface S1 of the protrusion 100P and the side surface S3 of the barrier layer 109. The ohmic contact layer 104 is disposed on the leakage current suppression layer 102 and contacts the side surface S2 of the protrusion 100P and the side surface S4 of the barrier layer 109.

In some embodiments, the semiconductor component 1 is implemented as a high-frequency device, wherein the substrate 10 is one of a silicon substrate, a silicon carbide substrate, an SOI substrate, and a QST substrate. The buffer layer 200 is an aluminum gallium nitride (AlGaN) layer. The barrier layer 109 is an aluminum gallium nitride layer. The semiconductor layer 100 is a wide energy-gap gallium nitride (GaN) layer. The semiconductor layer 100 and the barrier layer 109 form a heterostructure (AlGaN/GaN heterostructure). The electrode layers 105, 106, and 108 are respectively used as a source electrode, a drain electrode, and a gate electrode. The materials of the electrode layers 105, 106, and 108 include Ag, Au, TiN, Au/Ti, Au/Mo/Ti, Au/Si/Ti, or the like. In some embodiments, the materials of the electrode layers 105, 106, and 108 include Ti/Al/Ni/Au with respective thicknesses of 30 nm/200 nm/40 nm/10 nm. In some embodiments, the materials of the electrode layers 105, 106, and 108 include Ti/Al/Ni/Au with respective thicknesses of 20 nm/220 nm/55 nm/45 nm. In some embodiments, the materials of the electrode layers 105, 106, and 108 include Ti/Al/Mo/Au with respective thicknesses of 15 nm/60 nm/35 nm/50 nm. In some embodiments, the materials of the electrode layers 105, 106, and 108 include Ta/Si/Ti/Al/Ni/Ta with respective thicknesses of 5 nm/5 nm/20 nm/120 nm/40 nm/30 nm. In some embodiments, the materials of the electrode layers 105, 106, and 108 include Ta/Ti/Al/Mo/Au with respective thicknesses of 10 nm/30 nm/90 nm/40 nm/25 nm. In some embodiments, the material of the electrode layers 105, 106, 108 includes Si/Ti/Al/Ni/Au, wherein the thickness of the Si layer is 3 nm or 6 nm. In some embodiments, the materials of the electrode layers 105, 106, and 108 include Ti/Al/Ti/Au with respective thicknesses of 30 nm/200 nm/30 nm/10 nm.

In order to reduce the contact resistance between the source electrode 105 and the drain electrode 106, ohmic contact layers 103 and 104 are disposed in the semiconductor component 1 so as to increase the high-frequency power gain. In some embodiments, the materials of the ohmic contact layers 103 and 104 may include the N-type gallium nitride, the N-type indium nitride, ZnO, SiC, AlInGaN, Ti, Al, Cr, or metals having the metal work function less than 4.49 eV. In some preferred embodiments, the ohmic contact layers 103 and 104 are doped with silicon or germanium, wherein the doping concentration is between 10¹⁸ cm⁻³ and 10²¹ cm⁻³. Accordingly, the contact resistance is further reduced.

The top surface T3 of the protrusion 100P is located between the top surfaces 103T and 104T of the ohmic contact layers 103 and 104 and the top surfaces 101T and 102T of the leakage current suppression layers 101 and 102. A two-dimensional electron gas with a low resistance value is formed at the heterointerface (ie, the top surface T3 of the protrusion 100P), and the two-dimensional electron gas acts as a channel layer 100C. That is, side surfaces of the channel layer 100C contact the ohmic contact layers 103 and 104. Accordingly, the contact resistance is further reduced.

It should be particularly noted that the semiconductor components in some comparative examples do not have the leakage current suppression layers 101 and 102 disposed therein. That is, the ohmic contact layer 103 contacts the top surface T1, and the ohmic contact layer 104 contacts the top surface T2. In this manner, when the semiconductor component is in operation, a slight current would leak downward to the buffer layer 200 or the substrate 10. In contrast, the semiconductor component 1 according to the embodiment of the present invention has the leakage current suppression layers 101 and 102 disposed therein. Therefore, the ohmic contact layer 103 does not directly contact the top surface T1, and the ohmic contact layer 104 does not directly contact the top surface T2. The abovementioned current-leakage situation in the comparative examples would not occur in the semiconductor component 1 of the present embodiment. In some embodiments of the present invention, the materials of the leakage current suppression layers 101 and 102 may include one of SiO₂, SiN, Ga₂O₃, (AlₓGa₁₋ₓ)₂O₃, Al₂O₃, AlN, BN or alike wide band-gap materials. However, the invention is not limited thereto.

In the embodiment shown in FIG. 3, the semiconductor component 1 further includes a leakage current suppression layer 107, wherein the barrier layer 109, the leakage current suppression layer 107 and the electrode layer 108 are stacked in sequence. However, the present invention is not limited thereto. In some embodiments, the electrode layer 108 is directly disposed on the barrier layer 109.

Refer to FIG. 3. In this embodiment, the ohmic contact layer 103 has an oblique side surface 103S away from the side surface S1 of the protrusion 100P. The oblique side surface 103S is inclined with respect to the leakage current suppression layer 101 and is in contact with the electrode layer 105. The ohmic contact layer 104 has an oblique side surface 104S away from the side surface S2 of the protrusion 100P. The oblique side surface 104S is inclined with respect to the leakage current suppression layer 102 and is in contact with the electrode layer 106. The top surface 109T of the barrier layer 109 is located between the top surfaces 103T, 104T of the ohmic contact layers 103, 104 and the top surface T3 of the protrusion 100P.

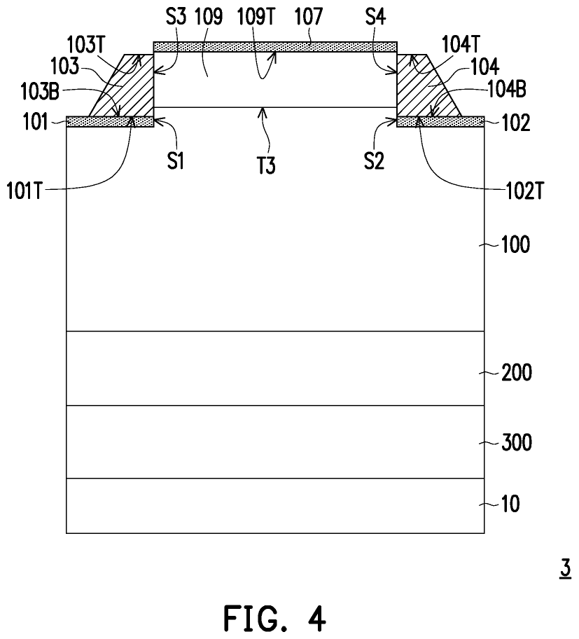

In contrast, refer to FIG. 4, which illustrates a partial structural diagram of a semiconductor component 3 according to another embodiment of the present invention. The top surfaces 103T and 104T of the ohmic contact layers 103 and 104 of the semiconductor component 3 are located between the top surface 109T of the barrier layer 109 and the top surface T3 of the protrusion 100P.

Refer to FIG. 3 and FIG. 4. Regarding the semiconductor component 1, the area of the bottom surface 103B of the ohmic contact layer 103 is equal to the area of the top surface 101T of the leakage current suppression layer 101, and the area of the bottom surface 104B of the ohmic contact layer 104 is equal to the area of the top surface 102T of the leakage current suppression layer 102. However, the present invention is not limited thereto. Regarding the semiconductor component 3, the area of the bottom surface 103B of the ohmic contact layer 103 may be smaller than the area of the top surface 101T of the leakage current suppression layer 101, and the area of the bottom surface 104B of the ohmic contact layer 104 may be smaller than the area of the top surface 102T of the leakage current suppression layer 102, as shown in FIG. 4.

To sum up, in the semiconductor component of the embodiment of the present invention, the leakage current suppression layer is disposed between the ohmic contact layer and the semiconductor layer, wherein the ohmic contact layer is used to reduce the contact resistance so as to increase the high-frequency power gain. The leakage current suppression layer is used to prevent current from leaking downward to the buffer layer or substrate of the semiconductor component, when the semiconductor component is in use. Accordingly, the semiconductor component may also have higher efficiency with high-frequency power gain.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A semiconductor component, comprising:
a semiconductor layer, wherein the semiconductor layer has a protrusion and two top surfaces of the semiconductor layer on a side of the semiconductor layer, the two top surfaces of the semiconductor layer are adjacent to the protrusion, the protrusion comprising a top surface and two side surfaces, one of the two side surfaces of the protrusion is adjacent between the top surface of the protrusion and one of two top surfaces of the semiconductor layer, and the other one of the two side surfaces of the protrusion is adjacent between the top surface of the protrusion and the other one of two top surfaces of the semiconductor layer;
a barrier layer, disposed on the top surface of the protrusion, wherein the barrier layer comprising two side surfaces;
two leakage current suppression layers, respectively disposed on the two top surfaces of the semiconductor layer;
two ohmic contact layers, respectively disposed on the two leakage current suppression layers, wherein the two ohmic contact layers are in contact with the two side surfaces of the protrusion and the two side surfaces of the barrier layer, wherein the two ohmic contact layers do not contact the two top surfaces of the semiconductor layer; and
two electrode layers, respectively disposed on the two ohmic contact layers.

2. The semiconductor component according to claim 1, wherein the top surface of the protrusion is disposed between top surfaces of the two ohmic contact layers and top surfaces of the two leakage current suppression layers.

3. The semiconductor component according to claim 1, wherein materials of the two leakage current suppression layers comprise SiO₂, SiN, Ga₂O₃, (AlₓGa₁₋ₓ)₂O₃, Al₂O₃, AlN or BN.

4. The semiconductor component according to claim 1, wherein the two ohmic contact layers comprise at least one of N-type gallium nitride, N-type indium nitride, ZnO, SiC, AlInGaN, Ti, Al, and Cr.

5. The semiconductor component according to claim 4, wherein the two ohmic contact layer are doped with silicon or germanium with a doping concentration between 10¹⁸ cm⁻³ and 10²¹ cm⁻³.

6. The semiconductor component according to claim 1, wherein the semiconductor layer comprises a channel layer, and the two ohmic contact layers contact side surfaces of the channel layer.

7. The semiconductor component according to claim 1, further comprising a buffer layer disposed on another side of the semiconductor layer.

8. The semiconductor component according to claim 7, further comprising a substrate, wherein the buffer layer is disposed between the substrate and the semiconductor layer, and the substrate is one of a silicon substrate, a silicon carbide substrate, an SOI substrate, and a QST substrates.

9. The semiconductor component according to claim 1, wherein bottom surfaces of the two ohmic contact layers are in contact with and smaller than top surfaces of the two leakage current suppression layers.

10. The semiconductor component according to claim 1, wherein the two leakage current suppression layers are respectively a first leakage current suppression layer and a second leakage current suppression layer, and the two electrode layers are respectively a first electrode layer and a second electrode layer, and the semiconductor component further comprises a third leakage current suppression layer and a third electrode layer, wherein the barrier layer, the third leakage current suppression layer and the third electrode layer are stacked in sequence.

11. The semiconductor component according to claim 10, wherein the two ohmic contact layers has two side surfaces away from the two side surfaces of the protrusion, and the two side surfaces of the ohmic contact layers are inclined with respect to the two leakage current suppression layer, and the first electrode layer and the second electrode layer respectively contact the side surfaces of the two ohmic contact layers.

12. The semiconductor component according to claim 1, wherein the two ohmic contact layers comprises a metal with a metal work function less than 4.49 eV.
